(19) United States
(12) Patent Application Publication
(10) Pub. No.: US 2024/0313508 A1
(43) Pub. Date: Sep. 19, 2024

(54) LIGHT SOURCE DEVICE AND ELECTRONIC APPARATUS

(71) Applicant: SONY GROUP CORPORATION, TOKYO (JP)

(72) Inventor: YUSUKE OGAWA, TOKYO (JP)

(21) Appl. No.: 18/575,634

(22) PCT Filed: Mar. 16, 2022
(86) PCT No.: PCT/JP2022/011865

§ 371 Date: Dec. 29, 2023

(30) Foreign Application Priority Data
Jul. 13, 2021 (JP) 2021-116008

(51) Int. Cl. H01S 5/20; H01S 5/02; H01S 5/183

(52) U.S. Cl. CPC H01S 5/2031; H01S 5/0216; H01S 5/18327

(57) ABSTRACT

A light source device according to an embodiment of the present disclosure includes: an optical waveguide path including a diffraction grating; a light source unit that outputs laser light having an optical center axis inclined, with respect to the diffraction grating, in a direction in which the optical waveguide path extends; and a light receiving unit that receives light leaking from the optical waveguide path through the diffraction grating from among the laser light outputted from the light source.

### TECHNICAL FIELD

The present disclosure relates to a light source device and an electronic apparatus.

### BACKGROUND ART

As a light source for an AR (Augmented Reality) eye wear or a laser display, study has been made on a technique of multiplexing three RGB colors of laser light in an optical waveguide path. For example, the invention described in Patent Literature 1 discloses a technique of highly efficiently multiplexing three visible lights differing from each other, within an optical waveguide path. In addition, as a light source for an AR eye wear, study has been started on a VCSEL (surface emitting laser) as an eye-safe light source having low power consumption. By combining these two techniques, it is possible to achieve an ultra-small RGB light source having low power consumption.

### CITATION LIST

### Patent Literature

Patent Literature 1: Japanese Unexamined Patent Application Publication No. 2013-195603
Patent Literature 2: Japanese Unexamined Patent Application Publication No. 2017-054132
Patent Literature 3: Japanese Unexamined Patent Application Publication No. 2004-177816
Patent Literature 4: Japanese Unexamined Patent Application Publication No. 2017-513056

### SUMMARY OF THE INVENTION

Incidentally, a technique of combining a VCSEL and an optical waveguide path is disclosed, for example, in Patent Literatures 2 to 4. However, in a case of the invention described in Patent Literatures 2 to 4, highly accurate placement and processes are necessary. In addition, in order to stably control the VCSEL, it is necessary to monitor an optical output. Thus, it is desirable to provide a light source device and an electronic apparatus, which are able to combine lights and monitor the optical output using an easily achievable configuration.

A light source device according to one embodiment of the present disclosure includes: an optical waveguide path including a diffraction grating; a light source unit that outputs laser light having an optical center axis inclined, with respect to the diffraction grating, in a direction in which the optical waveguide path extends; and a light receiving unit that receives light leaking from the optical waveguide path through the diffraction grating from among the laser light outputted from the light source.

An electronic unit apparatus according to one embodiment of the present disclosure includes the light source device.

With the light source device and the electronic apparatus according to the embodiment of the present disclosure, laser light is outputted from the light source unit, and the laser light has an optical center axis inclined, with respect to the diffraction grating in the optical waveguide path, in a direction in which the optical waveguide path extends. With this configuration, the laser light is propagated within the optical waveguide path toward one direction of the optical waveguide path due to diffraction with the diffraction grating. In addition, the light receiving unit receives a component (leakage light) of the laser light that leaks from the optical waveguide path through the diffraction grating. Thus, the light that is propagated within the optical waveguide path is monitored on the basis of detection of light at the light receiving unit.

### BRIEF DESCRIPTION OF DRAWING

FIG. 1 is a diagram illustrating an example of the configuration at an upper surface of a light source device according to the embodiment of the present disclosure.

FIG. 2 is a diagram illustrating an example of a cross-sectional configuration at the line A-A in FIG. 1.

FIG. 3 is a diagram illustrating an example of the configuration of the bottom surface of the light source unit and a light receiving unit in FIG. 2.

FIG. 4 is a diagram illustrating the bottom surface of the light source unit in FIG. 3 in an enlarged manner.

FIG. 5 is a diagram illustrating an example of a cross-sectional configuration at the line A-A in FIG. 4.

FIG. 6 is a diagram illustrating an example of the configuration at an upper surface of the optical waveguide substrate in FIG. 2.

FIG. 7 is a diagram illustrating an example of the schematic configuration of the diffraction grating in FIG. 2.

FIG. 8 is a diagram illustrating an example of the schematic configuration of the diffraction grating in FIG. 2.

FIG. 9 is a diagram illustrating one modification example of the light source device in FIG. 1.

FIG. 10 is a diagram illustrating one modification example of the light source device in FIG. 1.

FIG. 11 is a diagram illustrating one modification example of the light source device in FIG. 1.

FIG. 12 is a diagram illustrating one modification example of the light source device in FIG. 1.

FIG. 13 is a diagram illustrating one modification example of the light source device in FIG. 1.

FIG. 14 is a diagram illustrating one modification example of a method of mounting the light source unit in FIG. 2.

FIG. 15 is a diagram illustrating the bottom surface of the light source unit in FIG. 14 in an enlarged manner.

FIG. 16 is a diagram illustrating one modification example of a method of mounting the light source unit in FIG. 2.

FIG. 17 is a diagram illustrating one modification example of a method of mounting the light source unit in FIG. 2.

FIG. 18 is a diagram illustrating one modification example of a method of mounting the light source unit in FIG. 2.

FIG. 19 is a diagram illustrating one modification example of a method of mounting the light source unit in FIG. 2.

FIG. 20 is a diagram illustrating an example of the configuration of the bottom surface of the light source unit and the light receiving unit in FIG. 2.

FIG. 21 is a diagram illustrating one modification example of a planar configuration of the optical waveguide substrate in FIG. 2.

FIG. 22 is a diagram illustrating one modification example of the light source device in FIG. 1.

FIG. 23 is a diagram illustrating an application example of a light source device.

### MODES FOR CARRYING OUT THE INVENTION

Below, modes for carrying out the present disclosure will be described in detail with reference to the drawings. The following description is given as one specific example of the present disclosure, and the present disclosure is not limited to the following modes. In addition, as for the arrangement, dimensions, dimension ratios, and the like of individual constituent elements, the present disclosure is not limited to those illustrated in each drawing. Note that description will be made in the following order.

### 1. Embodiment

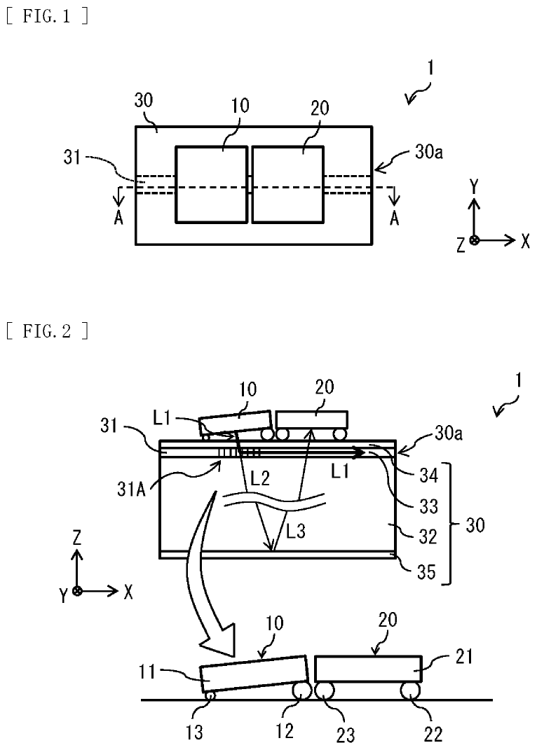

Example in which a light source unit and a light receiving unit are mounted at a common surface of an optical waveguide substrate (FIGS. 1 to 8).

### 2. Modification Example

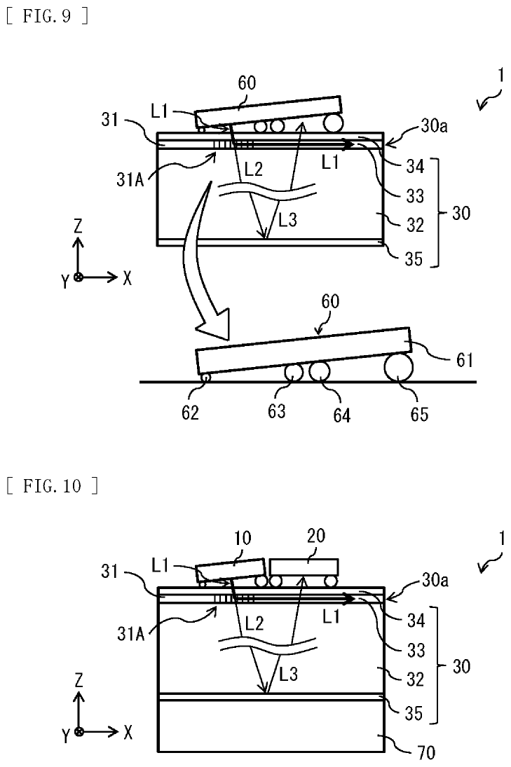

Modification Example A: Example in which a light source unit and a light receiving unit are integrally provided (FIG. 9).

Modification Example B: Example in which a support substrate is provided below a mirror layer (FIG. 10).

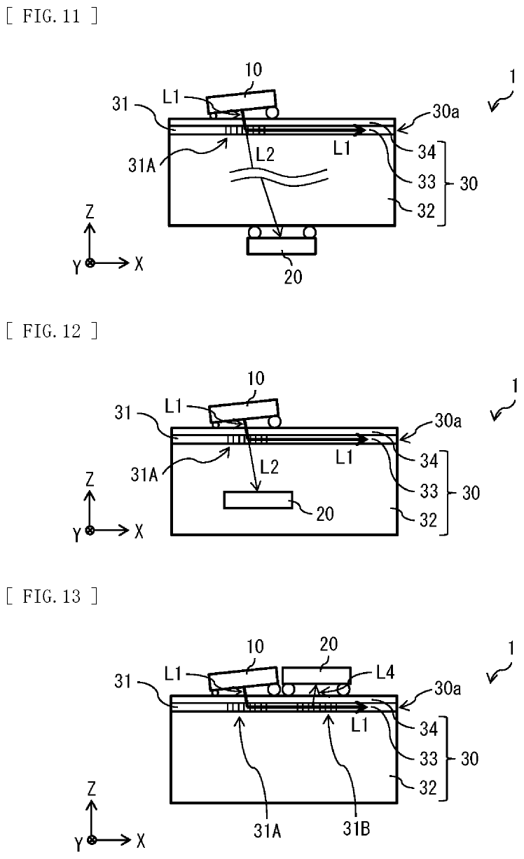

Modification Example C: Example in which a light receiving unit is mounted at a rear surface of an optical waveguide substrate (FIG. 11).

Modification Example D: Example in which a light receiving unit is provided within an optical waveguide substrate (FIG. 12).

Modification Example E: Example in which a diffraction grating for a light receiving unit is provided (FIG. 13).

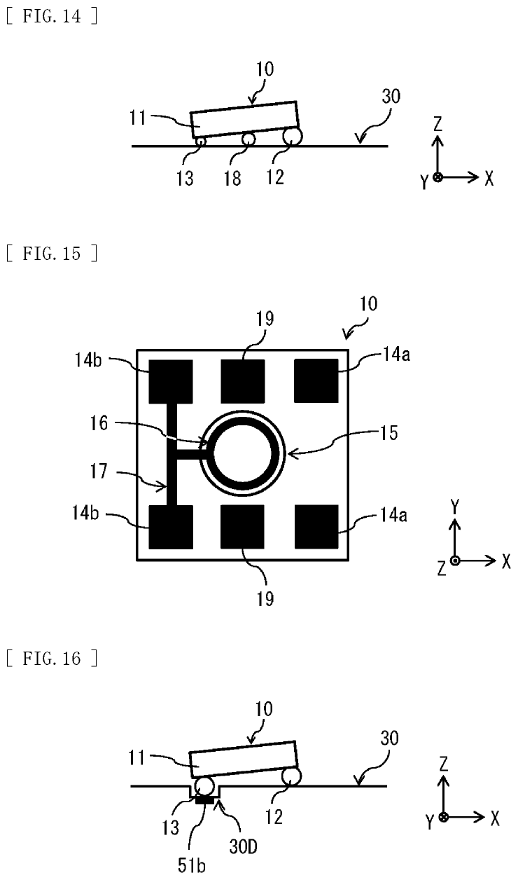

Modification Example F: Variation of a method of mounting a light source unit (FIGS. 14 to 21).

Modification Example G: Modification example of a diffraction grating (FIG. 22).

Modification Example H: Example in which an underfill is provided.

### 3. Application Example

Example in which a light source device is applied to eye glasses (FIG. 23).

### 1. Embodiment

### [Configuration]

Description will be made of a light source device 1 according to the embodiment of the present disclosure. FIG. 1 is a diagram illustrating an example of the configuration at an upper surface of the light source device 1. FIG. 2 is a diagram illustrating an example of a cross-sectional configuration of the light source device 1 at the line A-A in

FIG. 1. The light source device 1 is preferably used as a light source for an AR eye wear or a laser display.

The light source device 1 includes a light source unit 10, a light receiving unit 20, and an optical waveguide substrate 30. In the present embodiment, the light source unit 10 and the light receiving unit 20 are mounted at a common surface (upper surface) of the optical waveguide substrate 30. The light source unit 10 is mounted at the upper surface of the optical waveguide substrate 30, for example, with a plurality of joining sections 12 and a plurality of joining sections 13. The light receiving unit 20 is mounted at the upper surface of the optical waveguide substrate 30, for example, with a plurality of joining sections 22 and a plurality of joining sections 23. The light source unit 10 and the light receiving unit 20 are disposed side by side in a direction in which an optical waveguide path 31 within the optical waveguide substrate 30 extends. Note that the light source device 1 may further include a driving IC that drives the light source unit 10 and the light receiving unit 20.

The joining sections 12, 13, 22, and 23 includes, for example, a solder ball. The joining sections 13 are disposed further away from the light receiving unit 20 than the joining sections 12. The size of the joining section 13 (for example, the size of the solder ball that constitutes the joining section 13) is smaller than the size of the joining section 12 (for example, the size of the solder ball that constitutes the joining section 12). The solder material for the joining section 12 may be equal to the solder material for the joining section 13 or may differ from the solder material for the joining section 13. The light source unit 10 is, for example, in a form of a chip. In addition, the bottom surface of the light source unit 10 does not squarely face the upper surface (mounting surface) of the optical waveguide substrate 30, and is inclined in a direction in which the optical waveguide path 31 extends. The inclination of the light source unit 10 is controlled with a difference between the size of the joining sections 12 and the size of the joining section 13. Note that, in a case where the size of the solder ball is, for example, several tens of μm, it is possible to control the size of the solder ball with an error or approximately +1 μm.

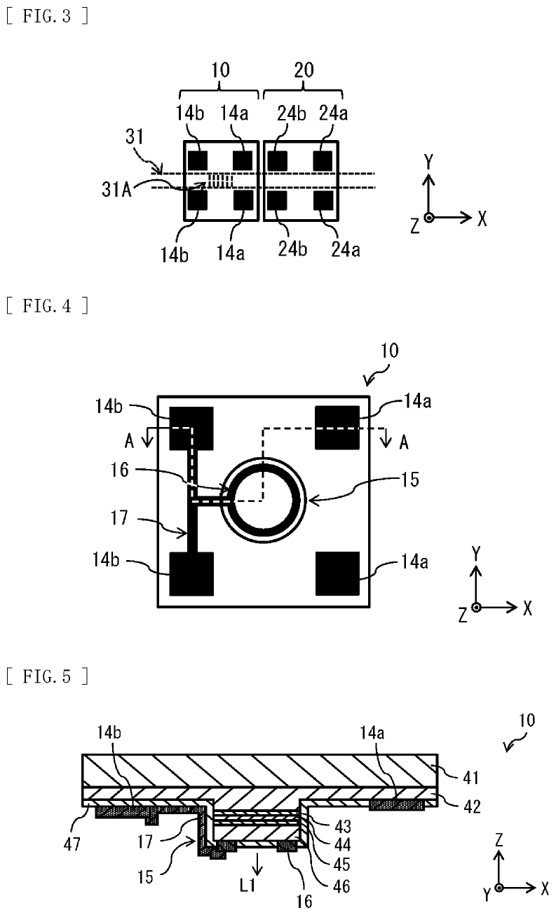

FIG. 3 is a diagram illustrating an example of the configuration of the bottom surfaces of the light source unit 10 and the light receiving unit 20. The light source unit 10 includes, for example, two pad sections 14a and two pad sections 14b provided at the bottom surface of the light source unit 10. The two pad sections 14a and the two pad sections 14b are disposed at substantially four corners of the bottom surface of the light source unit 10. This is because, by providing the joining section 12 at each of the pad sections 14a and providing the joining section 13 at each of the pad sections 14b to support the light source unit 10 at four points, the inclination angle of or the position of the light source unit 10 can be easily controlled. The two pad sections 14b are disposed further away from the light receiving unit 20 than the two pad sections 14a. The pad sections 14a and 14b include, for example, a metal material such as gold.

The light receiving unit 20 includes, for example, two pad sections 24a and two pad sections 24b provided at the bottom surface of the light receiving unit 20. The two pad sections 24a and the two pad sections 24b are disposed at substantially four corners of the bottom surface of the light receiving unit 20. This is because, by supporting the light receiving unit 20 at four points, it is possible to easily control the flatness of or the position of the light receiving unit 20. The two pad sections 24a are disposed further away from the light source unit 10 than the two pad sections 24b. The pad section 24a and 24b include, for example, a metal material such as gold.

FIG. 4 is a diagram illustrating the bottom surface of the light source unit 10 in FIG. 3 in an enlarged manner. A mesa section 15 that outputs laser light L1 is provided at the bottom surface of the light source unit 10. An electrode 16 used to input a current to the mesa section 15 is provided at the top face of the mesa section 15. For example, the electrode 16 has an annular shape having an opening provided at a portion that is opposed to a surface where the laser light L1 is outputted. A wiring line 17 that electrically couples the electrode 16 and the two pad sections 14b is provided at the bottom surface of the light source unit 10. The electrode 16 and the wiring line 17 include, for example, a metal material such as gold.

FIG. 5 is a diagram illustrating an example of a cross-sectional configuration at the line A-A in FIG. 4. The light source unit 10 includes a surface emitting-type semiconductor laser (VCSEL). For example, the surface emitting-type semiconductor laser includes a semiconductor layer in which a DBR (distributed Bragg reflector) layer 42, a spacer layer 43, an active layer 44, a spacer layer 45, and a DBR layer 46 including a current confining layer are stacked in this order at the rear surface of a substrate 41. Note that this semiconductor layer may include another functional layer (for example, a contact layer or the like). This semiconductor layer includes, for example, an AlGaAs-based semiconductor material. Note that the material for this semiconductor layer may include a semiconductor material based on a material other than an AlGaAs-based material. Of this semiconductor layer, a pillar-shaped mesa section 15 is formed at a portion of the DBR layer 42, the spacer layer 43, the active layer 44, the spacer layer 45, and the DBR layer 46. A current inputting region of a current confining layer is formed at a middle portion of the mesa section 15 in a stacking in-plane direction.

An insulating layer 47 that protects the surface emitting-type semiconductor laser is formed at the top face, the circumferential face, and the bottom face of the mesa section 15. The insulating layer 47 has an opening portion at the outer edge portion of the top face of the mesa section 15, and the electrode 16 is formed so as to be ohmic joined at the bottom surface of this opening portion. The electrode 16 is provided at a current path, at the DBR layer 46 side, of the surface emitting-type semiconductor laser. The insulating layer 47 also has an opening portion at the bottom face of the mesa section 15, and the pad section 14a is formed so as to be ohmic joined at the bottom surface (DBR layer 42) of this opening portion. The pad section 14a is provided at a current path, at the DBR layer 42 side, of the surface emitting-type semiconductor laser. The pad section 14b is formed at a portion of the insulating layer 47 that is formed at the front surface of the bottom face of the mesa section 15. Of the insulating layer 47, the wiring line 17 extends over the top face, the circumferential face, and the bottom face of the mesa section 15, and electrically couples the electrode 16 and the pad section 14b.

The light receiving unit 20 includes a photodiode that receives light (leakage light L2) leaking from the optical waveguide path 31 through a diffraction grating 31A, from among the laser light L1 outputted from the light source unit 10. The photodiode includes, for example, a semiconductor layer having P-N junction. For example, the light receiving unit 20 includes two electrodes 24a configured so as to be ohmic joined to a P-type semiconductor layer of a photo diode, and also includes an electrode 24b configured so as to be ohmic joined to an N-type semiconductor layer of a photodiode, as illustrated in FIG. 3.

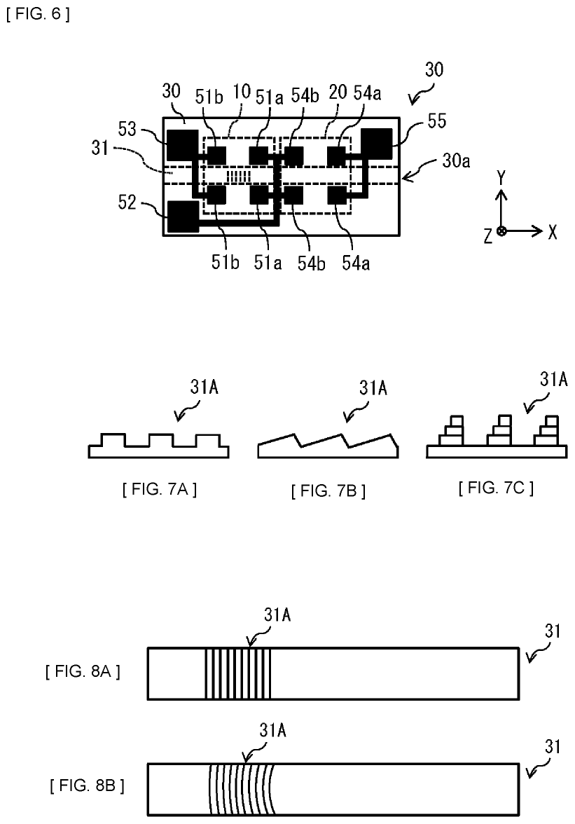

FIG. 6 is a diagram illustrating an example of the configuration at an upper surface of the optical waveguide substrate 30. At the upper surface of the optical waveguide substrate 30, the optical waveguide substrate 30 includes, for example, two pad sections 51a, two pad sections 51b, two pad sections 54a, two pad sections 54b, and lead-out sections 52, 52, and 55. The two pad sections 51a, the two pad sections 51b, the two pad sections 54a, the two pad sections 54b, and lead-out sections 52, 52, and 55 include, example, metal a material such as gold.

At the upper surface of the optical waveguide substrate 30, the two pad sections 51a and the two pad sections 51b are disposed at positions that are opposed to the light source unit 10. The two pad sections 51a are disposed at positions that are opposed to the two pad sections 14a. The two pad sections 51b are disposed at positions that are opposed to the two pad sections 14b. The two pad sections 51b are disposed further away from the light receiving unit 20 than the two pad sections 51a. At the upper surface of the optical waveguide substrate 30, the two pad sections 54a and the two pad sections 54b are disposed at positions that are opposed to the light receiving unit 20. The two pad sections 54a are disposed at positions that are opposed to the two pad sections 24a. The two pad sections 54b are disposed at positions that are opposed to the two pad sections 24b. The two pad sections 54a are disposed further away from the light source unit 10 than the two pad sections 54b.

The two pad sections 51b are coupled to a lead-out section 53 through a wiring line, for example. The two pad sections 54a are coupled to the lead-out section 55 through a wiring line, for example. The two pad sections 51a and the two pad sections 54b are coupled to the lead-out section 52 through a wiring line, for example. The lead-out sections 52, 53, and 55 are disposed at position that are not opposed to the light source unit 10 or the light receiving unit 20. For example, the lead-out sections 52, 53, and 55 are coupled through a bonding wire to a driving IC that drives the light source unit 10 and the light receiving unit 20.

The joining section 12 is provided between the pad section 14a and the pad section 51a, and is an electrically conductive member that couples the pad section 14a and the pad section 51a to each other. The joining section 13 is provided between the pad section 14b and the pad section 51b, and is an electrically conductive member that couples the pad section 14b and the pad section 51b to each other. The joining section 22 is provided between the pad section 24a and the pad section 54a, and is an electrically conductive member that couples the pad section 24a and the pad section 54a to each other. The joining section 23 is provided between the pad section 24b and the pad section 54b, and is an electrically conductive member that couples the pad section 24b and the pad section 54b to each other.

Note that a driving IC that drives the light source unit 10 may be provided within the light source unit 10. In this case, the pad sections 14a and 14b may be coupled to the driving IC that drives the light source unit 10. In addition, a driving IC that drives the light receiving unit 20 may be provided within the light receiving unit 20. In this case, the pad sections 24a and 24b may be coupled to the driving IC that drives the light receiving unit 20.

For example, as illustrated in FIG. 2, the optical waveguide substrate 30 includes a mounting surface (upper surface) for the light source unit 10 and the light receiving unit 20, and also includes a bottom surface. Furthermore, the optical waveguide substrate 30 includes the optical waveguide path 31 provided between the upper surface and the bottom surface so as to be parallel to the upper surface of the optical waveguide substrate 30, and also includes a mirror layer 35 provided at the bottom surface. For example, as illustrated in FIG. 2, the optical waveguide substrate 30 further includes a core layer 33 in which the optical waveguide path 31 is formed, and a pair of clad layers 32 and 34 between which the core layer 33 is interposed from the stacking direction. The clad layer 32 is provided between the core layer 33 and the mirror layer 35. The clad layer 34 is provided between the upper surface of the optical waveguide substrate 30 and the core layer 33.

The diffraction grating 31A is provided at a position of the optical waveguide path 31 that is opposed to the light source unit 10. The diffraction grating 31A is an optical element used to optically combine the optical waveguide path 31 and the light source unit 10. As the laser light L1 having an optical center axis inclined in a direction in which the optical waveguide path 31 extends enters the diffraction grating 31A, the diffraction grating 31A diffracts the obliquely entered laser light L1 in one direction (inclination direction of the laser light L1 (for example, the positive direction of the X axis in the drawing)) of the optical waveguide path 31, and causes it to be propagated within the optical waveguide path 31 toward the one direction (inclination direction of the laser light L1) of the optical waveguide path 31. The reason that the laser light L1 is caused to be entered obliquely with respect to the diffraction grating 31A in this manner is because the laser light L1 is caused to be diffracted only in the one direction (inclination direction of the laser light L1) of the optical waveguide path 31.

It is preferable that a center value of the angle of incidence (the angle of incidence of a component of the laser light L1 that is parallel to the optical center axis) of the laser light L1 relative to the diffraction grating 31A should fall in a range of not less than 4° and not more than 20°, and it is more preferable that this center value should fall in a range of not less than 5° and not more than 10°. This is because the laser light L1 is diverging light, and hence, as the angle of incidence reduces, it is more likely that the laser light L1 is diffracted not only in the one direction (inclination direction (positive direction of the X axis in the drawing) of the laser light L1) of the optical waveguide path 31 but also in the other direction (direction (negative direction of the X axis in the drawing) opposite to the inclination direction of the laser light L1) of the optical waveguide path 31. Whether or not the laser light L1 is diffracted only in the one direction (inclination direction of the laser light L1) of the optical waveguide path 31 is determined on the basis of a wavelength of the laser light L1, a pitch of the diffraction grating 31A, the angle of incidence of the laser light L1, the divergence angle of the laser light L1, and an effective refraction index of the optical waveguide path 31. Thus, a wavelength of the laser light L1, a pitch of the diffraction grating 31A, the angle of incidence of the laser light L1, and the divergence angle of the laser light L1 are set to conditions that cause the laser light L1 to be diffracted in the one direction (inclination direction of the laser light L1) of the optical waveguide path 31 and do not cause the laser light L1 to be diffracted in the other direction (direction opposite to the inclination direction of the laser light L1) of the optical waveguide path 31.

Incidentally, it is still a challenge to cause the laser light L1 entering the diffraction grating 31A to enter the optical waveguide path 31 at 100%. In actuality, a portion of the laser light L1 entering the diffraction grating 31A passes through the diffraction grating 31A or is refracted at the diffraction grating 31A or is diffracted at the diffraction grating 31A, thereby leaking from the optical waveguide path 31. A component (leakage light L2) of the laser light L1 that leaks out from the optical waveguide path 31 through the diffraction grating 31A is propagated through the clad layer 32, and then reaches the mirror layer 35 to be reflected. The light (reflected light L3) reflected in this manner is propagated through the clad layer 32, the core layer 33, and the clad layer 34, and then enters the light receiving unit 20. The mirror layer 35 may be configured so as to totally reflect the leakage light L2 or may be configured such that most of the leakage light L2 is reflected.

The diffraction grating 31A includes, for example, a binary diffraction grating (FIG. 7(A)), a blazed diffraction grating (FIG. 7(B)), a stepped diffraction grating (FIG. 7(C)), or the like. The binary diffraction grating has a symmetrical structure, and hence, can be easily designed and be achieved easily. On the other hand, the blazed diffraction grating and the stepped diffraction grating have an asymmetrical structure. Thus, they are slightly difficult in terms of design as compared with the binary diffraction grating, but they have an achievable configuration.

The diffraction grating 31A includes, for example, a linear diffraction grating (FIG. 8(A)), a focus grating (FIG. 8(B)), or the like. The linear diffraction grating has a configuration that can be easily designed and be achieved easily. However, in a case of the linear diffraction grating, when the optical waveguide path 31 is narrowed after the laser light L1 is combined with the optical waveguide path 31, it is necessary to narrow the optical waveguide path 31 using a long optical waveguide path 31. On the other hand, the focus grating involves slightly complicated design, as compared with the linear diffraction grating. However, with the focus grating, in a case where the optical waveguide path 31 is narrowed after the laser light L1 is combined with the optical waveguide path 31, it is possible to narrow the optical waveguide path 31 using a short optical waveguide path 31.

### [Effects]

Next, effects of the light source device 1 according to the present embodiment will be described.

Techniques of combining a VCSEL and an optical waveguide path are disclosed, for example, in Patent Literatures 2 to 4. However, in a case of the inventions described in Patent Literatures 2 to 4, highly accurate placement and processes are necessary. In addition, in order to stably control the VCSEL, it is necessary to monitor an optical output. However, in a case where light is split, the optical output largely reduces, and efficiency in use of light largely deteriorates.

On the other hand, with the present embodiment, the laser light L1 is outputted from the light source unit 10. The laser light L1 has an optical center axis inclined in a direction in which the optical waveguide path 31 extends and with respect to the diffraction grating 31A within the optical waveguide path 31. With this configuration, the laser light L1 is propagated within the optical waveguide path 31 toward one direction of the optical waveguide path 31 due to diffraction with the diffraction grating 31A. In addition, the light receiving unit 20 receives a component (leakage light L2) of the laser light L1 that leaks out from the optical waveguide path 31 through the diffraction grating 31A. Thus, the light that is propagated within the optical waveguide path 31 is monitored on the basis of detection of light at the light receiving unit 20. This makes it possible to combine lights and monitor the optical output using an easily achievable configuration.

In addition, with the present embodiment, light is not necessary to be split to perform monitoring. This makes it possible to monitor the optical output while suppressing a reduction in efficiency in user of light.

In addition, in the embodiment, the light source unit 10 is disposed so as to be inclined with respect to the upper surface of the optical waveguide substrate 30 or the diffraction grating 31A. This makes it possible to reduce feedback light in which a portion of the laser light L1 outputted from the light source unit 10 is returned to the light source unit 10. Thus, it is possible to achieve the light source unit 10 having reduced noise.

In addition, in the present embodiment, a wavelength of the laser light L1, a pitch of the diffraction grating 31A, the angle of incidence of the laser light L1, the divergence angle of the laser light L1, and an effective refraction index of the optical waveguide path 31 are set to conditions that cause the laser light L1 to be diffracted in the one direction (inclination direction of the laser light L1) of the optical waveguide path 31 and do not cause the laser light L1 to be diffracted in the other direction (direction opposite to the inclination direction of the laser light L1) of the optical waveguide path 31. Thus, it is possible to achieve high efficiency in use of light, as compared with a case where the laser light L1 is propagated in both directions of the optical waveguide path 31.

In addition, in the present embodiment, the light source unit 10 and the light receiving unit 20 are mounted at the upper surface of the optical waveguide substrate 30 in which the optical waveguide path 31 is provided. At this time, for example, in a case where the light source unit 10 and the light receiving unit 20 are mounted using a solder ball, it is possible to adjust the positions of the light source unit 10 and the light receiving unit 20 and adjust the inclination of the light source unit 10 in an accurate manner due to self-alignment through reflow of solder. Thus, it is possible to combine lights using an easily achievable configuration.

Furthermore, in the present embodiment, the bottom surface of the light source unit 10 is inclined in a direction in which the optical waveguide path 31 extends, with respect to the upper surface of the optical waveguide substrate 30. With this configuration, the laser light L1 outputted from the light source unit 10 enters obliquely with respect to the diffraction grating 31A. This makes it possible to prevent the laser light L1 from being propagated toward a direction opposite to the direction in which the laser light L1 is intended to be propagated. Thus, it is possible to monitor the optical output while suppressing a reduction in the efficiency in use of light.

In addition, in the present embodiment, the size of the joining section 13 is smaller than the size of the joining section 12. With this configuration, by controlling the size of the joining section 13, it is possible to incline the stacking surface of the VCSEL within the light source unit 10 in the direction in which the optical waveguide path 31 extends, with respect to the upper surface of the optical waveguide substrate 30. Here, for example, in a case where the light source unit 10 and the light receiving unit 20 are mounted using a solder ball, the size of the solder ball can be relatively easily controlled in a highly accurate manner. Thus, it is possible to accurately control the inclination of the light source unit 10.

### 2. Modification Example

Next, modification examples of the light source device 1 according to the embodiment described above will be described.

### Modification Example A

In the embodiment described above, the light source unit 10 and the light receiving unit 20 may be, for example, an integrally formed element (light source unit 60 having a light receiving function), as illustrated in FIG. 9. At this time, the light source unit 60 having a light receiving function includes, for example, a light source substrate 61 having a light receiving function in which a VCSEL and a photodiode are formed, and a plurality of joining sections (joining sections 62, 63, 64, and 65) coupled to pad sections of the light source substrate 61 having a light receiving function, as illustrated in FIG. 9. The joining section 62 corresponds to the joining section 13 in the embodiment described above. The joining section 63 corresponds to the joining section 12 in the embodiment described above. The joining section 64 corresponds to the joining section 23 in the embodiment described above. The joining section 65 corresponds to the joining section 22 in the embodiment described above.

The sizes of the plurality of joining sections (joining sections 62, 63, 64, and 65) gradually increase toward the one direction (inclination direction of the laser light L1) of the optical waveguide path 31. By controlling the sizes of the plurality of joining sections (joining sections 62, 63, 64, and 65) in this manner, it is possible to highly accurately control the inclination of the light source unit 60 having a light receiving function.

### Modification Example B

In the embodiment described above and the modification example thereof, a support substrate 70 that is in contact with the mirror layer 35 may be provided, for example, as illustrated in FIG. 10. The support substrate 70 includes, for example, a semiconductor substrate, a resin substrate, or the like. In a case of the configuration as described above, it is possible to more easily mount the light source unit 10 and the light receiving unit 20 at the optical waveguide substrate 30. Thus, it is possible to combine lights and monitor the optical output using an easily achievable configuration.

### Modification Example C

In the embodiment described above and the modification examples thereof, the light receiving unit 20 may be mounted at the rear surface of the optical waveguide substrate 30, for example, as illustrated in FIG. 11. At this time, the mirror layer 35 is not provided. Even in a case of the configuration as described above, the light receiving unit 20 is able to receive a component (leakage light L2) of the laser light L1 that leaks out from the optical waveguide path 31 through the diffraction grating 31A. Thus, it is possible to monitor the light that is propagated within the optical waveguide path 31, on the basis of detection of light at the light receiving unit 20. This makes it possible to monitor the optical output using an easily achievable configuration.

### Modification Example D

In the embodiment described above and the modification examples thereof, the light receiving unit 20 may be provided within the optical waveguide substrate 30, for example, as illustrated in FIG. 12. At this time, the mirror layer 35 may not be provided. Even in a case of the configuration as described above, the light receiving unit 20 is able to receive a component (leakage light L2) of the laser light L1 that leaks out from the optical waveguide path 31 through the diffraction grating 31A. Thus, it is possible to monitor the light that is propagated within the optical waveguide path 31, on the basis of detection of light at the light receiving unit 20. This makes it possible to monitor the optical output using an easily achievable configuration.

### Modification Example E

In the embodiment described above and the modification examples thereof, a diffraction grating 31B may be provided at a position of the optical waveguide path 31 that is opposed to the light receiving unit 20, in addition to the diffraction grating 31A, for example, as illustrated in FIG. 13. The diffraction grating 31B is an optical element that optically combines the optical waveguide path 31 and the light receiving unit 20. When the laser light L1 propagated within the optical waveguide path 31 enters the diffraction grating 31B, the diffraction grating 31B allows most of the laser light L1 to pass through and causes a portion of the laser light L1 to be diffracted to cause it to leak out from the optical waveguide path 31. Of the laser light L1 propagated within the optical waveguide path 31, a component (leakage light L4) of the laser light L1 that leaks out from the optical waveguide path 31 through the diffraction grating 31B enters the light receiving unit 20. This makes it possible to monitor the light that is propagated within the optical waveguide path 31, on the basis of detection of light at the light receiving unit 20. Thus, it is possible to monitor the optical output using an easily achievable configuration.

### Modification Example F

A method of mounting the light source unit 10 at the upper surface of the optical waveguide substrate 30 is not limited to the method described in the embodiment described above and the modification examples thereof.

It may be possible to employ a configuration in which a plurality of dummy pad sections 19 is provided at the rear surface of the light source unit 10, and the pad sections 19 and the pad sections provided at the upper surface of the optical waveguide substrate 30 are coupled to each other through the joining section 18, for example, as illustrated in FIGS. 14 and 15. The dummy pad sections 19 are electrically separated from the surface emitting-type semiconductor laser or the driving IC. In a case of the configuration as described above, it is possible to accurately control the inclination of the light source unit 10 even if the size of the light source unit 10 is relatively large. Thus, it is possible to combine lights using an easily achievable configuration.

In addition, it may be possible to employ a configuration in which a recessed portion 30D is provided at a portion of the upper surface of the optical waveguide substrate 30 at which a pad section 51b is formed, and the pad section 51b is provided at the bottom surface of the recessed portion 30D, for example, as illustrated in FIG. 16. In a case of the configuration as described above, it is possible to accurately control the inclination of the light source unit 10 while setting the size of the joining section 13 equal to the size of the joining section 12. Thus, it is possible to combine lights using an easily achievable configuration.

Furthermore, it may be possible to employ a configuration in which a protruding portion 10M is provided at a portion of the bottom surface of the light source unit 10 at which a pad section 14a is formed, and the pad section 14a is formed at the top face of the protruding portion 10M, for example, as illustrated in FIG. 17. In a case of the configuration as described above, it is possible to accurately control the inclination of the light source unit 10 while setting the size of the joining section 13 equal to the size of the joining section 12. Thus, it is possible to combine lights using an easily achievable configuration.

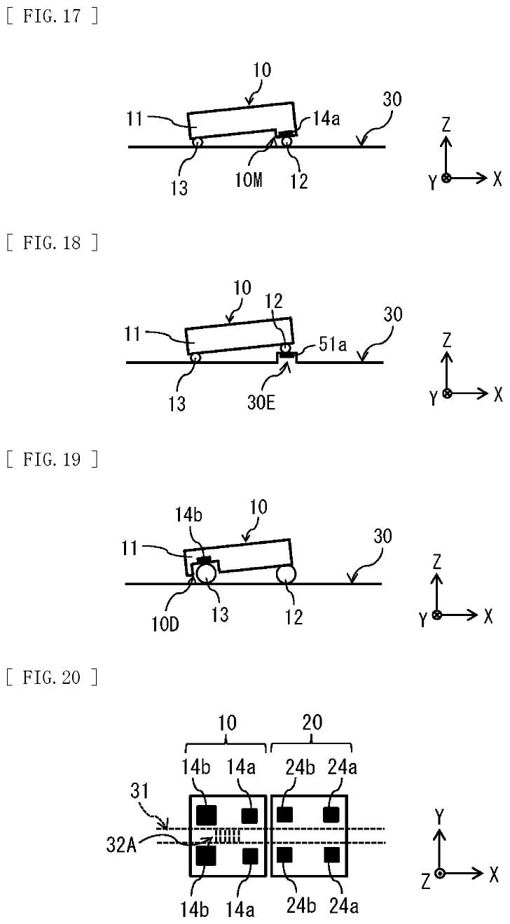

Furthermore, it may be possible to employ a configuration in which a protruding portion 30E is provided at a portion of the upper surface of the optical waveguide substrate 30 at which a pad section 51a is formed, and the pad section 51a is provided at the top face of the protruding portion 30E, for example, as illustrated in FIG. 18. In a case of the configuration as described above, it is possible to accurately control the inclination of the light source unit 10 while setting the size of the joining section 13 equal to the size of the joining section 12. Thus, it is possible to combine lights using an easily achievable configuration.

In addition, it may be possible to employ a configuration in which a recessed portion 10D is provided at a portion of the bottom surface of the light source unit 10 at which a pad section 14b is formed, and the pad section 14b is provided at the bottom surface of the recessed portion 10D, for example, as illustrated in FIG. 19. In a case of the configuration as described above, it is possible to accurately control the inclination of the light source unit 10 while setting the size of the joining section 13 equal to the size of the joining section 12. Thus, it is possible to combine lights using an easily achievable configuration.

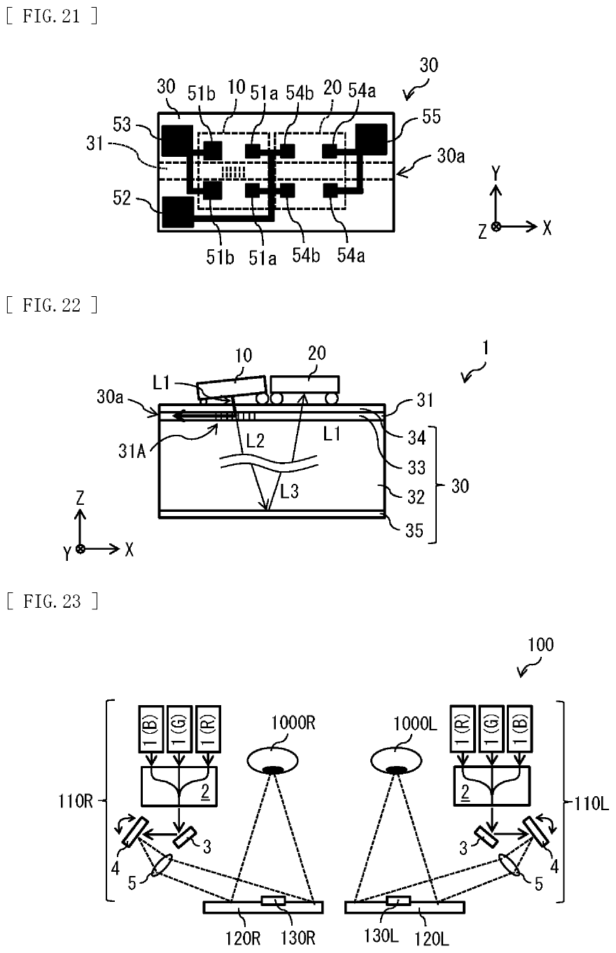

Furthermore, the size of the pad section 14b, 51b may be larger than the size of the pad section 14a, 51a, for example, as illustrated in FIGS. 20 and 21. In a case of the configuration as described above, for example, when the reflow is performed in a manufacturing process, the area of the pad section 14a, 51a in which a solder ball is wet and spreads is larger than that of the pad section 14b, 51b. Thus, in a case where all the sizes of the solder balls before the reflow are made equal, the height of the solder ball between sections 14b and 51b after the reflow is lower than the height of the solder ball between pad sections 14a and 51a after mounting. Thus, by controlling the sizes of the pad sections 14a, 14b, 51a, and 51b, it is possible to accurately control the inclination of the light source unit 10. Thus, it is possible to combine lights using an easily achievable configuration.

### Modification Example G

In addition, in the embodiment described above and the modification examples thereof, it may be possible to employ a configuration in which, when the laser light L1 enters the diffraction grating 31A, the diffraction grating 31A diffracts the laser light L1 in a predetermined direction (direction (for example, the negative direction of the X axis in the drawing) opposite to the inclination direction of the laser light L1) of the optical waveguide path 31, and causes the laser light L1 to be propagated within the optical waveguide path 31 toward the predetermined direction (direction opposite to the inclination direction of the laser light L1) of the optical waveguide path 31, for example, as illustrated in FIG. 22. Even in a case of the configuration as described above, it is possible to monitor the optical output using an easily achievable configuration.

### Modification Example H

Furthermore, in the embodiment described above and the modification examples thereof, it may be possible to provide an underfill that fills a space generated between the bottom surface of the light source unit 10 and the upper surface of the optical waveguide substrate 30.

### Modification Example I

In addition, in the embodiment described above and the modification examples thereof, each of the pad sections 14a and 14b may be dummy pad sections that are electrically separated from the surface emitting-type semiconductor laser or the driving IC. Even in a case of the configuration as described above, it is possible to monitor the optical output using an easily achievable configuration.

### 3. Application Example

Next, description will be made of an application example of the light source device 1 according to the embodiment described above and the modification examples thereof.

FIG. 23 is a diagram illustrating an example of the schematic configuration of eye glasses 100 including the light source device 1 according to the embodiment described above and the modification examples thereof. The eye glasses 100 include an image projection unit 110R for a right eye, a combiner 120R for a right eye, and an imaging section 130R for a right eye. The eye glasses 100 further include an image projection unit 110L for a left eye, a combiner 120L for a left eye, and an imaging section 130L for a left eye.

The image projection units 110R and 110L include a light source device 1(R) that outputs R (red) light, a light source device 1(G) that outputs G (green) light, a light source device 1(B) that outputs B (blue) light, and an optical waveguide path 2 that multiplexes the R light, the G light, and the B light. The image projection unit 110R further includes a mirror 3 that reflects white light generated through multiplexing at the optical waveguide path 2, and a scanning mirror 4 that scans the white light reflected at the mirror 3 in two axial directions on the front surface of the combiner 120R through a lens 5. The image projection unit 110L further includes a mirror 3 that reflects white light generated through multiplexing at the optical waveguide path 2, and a scanning mirror 4 that scans the white light reflected at the mirror 3 in two axial directions on the front surface of the combiner 120L through a lens 5.

The combiner 120R diffracts light imaged on the front surface of the combiner 120R by the image projection unit 110R, and projects it on a retina of the right eye 1000R. The imaging section 130R acquires image data containing the right eye 1000R through imaging, and detects a position of the right eye 1000R on the basis of the acquired image data. The imaging section 130R outputs the detected position of the right eye 1000R to the image projection unit 110R. The image projection unit 110R controls scanning of the scanning mirror 4 such that light is projected at the position of the right eye 1000R acquired from the imaging section 130R.

The combiner 120L diffracts light imaged on the front surface of the combiner 120L by the image projection unit 110L, and projects it on a retina of the left eye 1000L. The imaging section 130L acquires image data containing the left eye 1000L through imaging, and detects a position of the left eye 1000L on the basis of the acquired image data. The imaging section 130L outputs the detected position of the left eye 1000L to the image projection unit 110L. The image projection unit 110L controls scanning of the scanning mirror 4 such that light is projected at the position of the left eye 1000L acquired from the imaging section 130L.

In the present application example, the light source device 1 according to the embodiment described above and the modification examples thereof is used as a light source for the image projection units 110R and 110L. Thus, in the image projection units 110R and 110L, it is possible to combine lights and monitor the optical output using an easily achievable configuration.

These are descriptions of the present disclosure by giving the embodiment. However, the present disclosure is not limited to the embodiment described above, and various modifications are possible. Note that the effects described in the present description are merely given as examples. The effects of the present disclosure are not limited to the effects described in the present description. The present disclosure may have effects other than the effects described in the present description.

In addition, the present disclosure is able to take the following configurations, for example.

(1)

A light source device including:
an optical waveguide path including a first diffraction grating;
a light source unit that outputs laser light having an optical center axis inclined, with respect to the first diffraction grating, in a direction in which the optical waveguide path extends; and
a light receiving unit that receives light leaking from the optical waveguide path through the first diffraction grating from among the laser light outputted from the light source.

(2)

The light source device according to (1), in which
a wavelength of the laser light, a pitch of the first diffraction grating, an angle of incidence of the laser light with respect to the first diffraction grating, a divergence angle of the laser light, and an effective refraction index of the optical waveguide path are set to a condition that causes the laser light to be diffracted in one direction of the optical waveguide path and does not cause the laser light to be diffracted in another direction of the optical waveguide path.

(3)

The light source device according to (2), in which
a center value of the angle of incidence of the laser light falls in a range of not less than 4° and not more than 20°.

(4)

The light source device according to any one of (1) to (3), further including
an optical waveguide substrate including a first main surface and a second main surface that is opposed to the first main surface,
   the optical waveguide path provided between the first main surface and the second main surface, the optical waveguide path being parallel to the first main surface, and
   a mirror layer provided at the second main surface, in which
the light source unit and the light receiving unit are both mounted at the first main surface.

(5)

The light source device according to (4), in which
the light source unit includes
   an active layer,
   first and second DBR (distributed Bragg reflector) layers between which the active layer is interposed,
   a first pad section provided to be relatively spaced apart from the light receiving unit, and
   a second pad section provided at a position that is relatively close to the light receiving unit,
the optical waveguide substrate includes
   a third pad section provided at a position that is opposed to the first pad section, and
   a fourth pad section provided at a position that is opposed to the second pad section, and
the light source unit further includes
   a first joining section having an electrically conductive property provided between the first pad section and the third pad section and coupling the first pad section and the third pad section to each other, and
   a second joining section having an electrically conductive property provided between the second pad section and the fourth pad section and coupling the second pad section and the fourth pad section to each other.

(6)

The light source device according to (5), in which
a bottom surface of the light source unit is inclined, with respect to the first main surface, in a direction in which the optical waveguide path extends.

(7)

The light source device according to (6), in which
a size of the first joining section is smaller than a size of the second joining section.

(8)

The light source device according to (6), in which
sizes of the first pad section and the third pad section are larger than sizes of the second pad section and the fourth pad section.

(9)

The light source device according to any one of (1) to (8), in which
the light source unit and the light receiving unit are integrally formed.

(10)

The light source device according to (1), further including
an optical waveguide substrate including
   a first main surface and a second main surface that is opposed to the first main surface, and
   the optical waveguide path provided between the first main surface and the second main surface, the optical waveguide path being parallel to the first main surface, in which
the light source unit is mounted at the first main surface, and
the light receiving unit is mounted at the second main surface.

(11)

The light source device according to (1), further including
an optical waveguide substrate including
   a first main surface and a second main surface that is opposed to the first main surface,
   the optical waveguide path provided between the first main surface and the second main surface, the optical waveguide path being parallel to the first main surface, and
   the light receiving unit, in which
the light source unit is mounted at the first main surface.

(12)

The light source device according to (1), in which
the optical waveguide path further includes a second diffraction grating, and
the light receiving unit is disposed at a position configured to receive light leaking from the optical waveguide path through the second diffraction grating from among the laser light outputted from the light source.

(13)

The light source device according to (6), in which
the optical waveguide substrate includes a recessed portion at a portion at which the third pad section is formed, and
the third pad section is disposed at a bottom surface of the recessed portion.

(14)

The light source device according to (6), in which
the light source unit includes a protruding portion at a portion at which the second pad section is formed, and
the second pad section is disposed at a top face of the protruding portion.

(15)

The light source device according to (6), in which
the optical waveguide substrate includes a protruding portion at a portion at which the fourth pad section is formed, and
the fourth pad section is disposed at a top face of the protruding portion.

(16)

The light source device according to (6), in which
the light source unit includes a recessed portion at a portion at which the first pad section is formed, and
the first pad section is disposed at a bottom surface of the recessed portion.

(17)

The light source device according to (5), in which
the first joining section and the second joining section include solder.

(18)

An electronic apparatus including:
a light source device,
the light source device including
   an optical waveguide path including a first diffraction grating,
   a light source unit that outputs laser light having an optical center axis inclined, with respect to the first diffraction grating, in a direction in which the optical waveguide path extends, and
   a light receiving unit that receives light leaking from the optical waveguide path through the first diffraction grating from among the laser light outputted from the light source.

With the light source device and the electronic apparatus according to the embodiment of the present disclosure, laser light is outputted from the light source unit. The laser light has an optical center axis inclined, with respect to the diffraction grating within the optical waveguide path, in a direction in which the optical waveguide path extends. With this configuration, laser light is propagated within the optical waveguide path toward one direction of the optical waveguide path due to diffraction with the diffraction grating. In addition, the light receiving unit receives a component (leakage light) of the laser light that leaks from the optical waveguide path through the diffraction grating. Thus, the light that is propagated within the optical waveguide path is monitored on the basis of detection of light at the light receiving unit. Thus, it is possible to combine lights using an easily achievable configuration, and it is also possible to monitor the optical output while suppressing a reduction in the efficiency in use of light. Note that effects of the present disclosure are not necessarily limited to the effects described here, and may be any effects described in the present description.

The present application claims priority based on Japanese Patent Application No. 2021-116008 filed on Jul. 13, 2021 with Japan Patent Office, the entire contents of which are incorporated in this application by reference.

It should be understood by those skilled in the art that various modifications, combinations, sub-combinations and alterations may occur depending on design requirements and other factor, and they are within the scope of the appended claims or the equivalents thereof.

1. A light source device comprising:
an optical waveguide path including a first diffraction grating;
a light source unit that outputs laser light having an optical center axis inclined, with respect to the first diffraction grating, in a direction in which the optical waveguide path extends; and
a light receiving unit that receives light leaking from the optical waveguide path through the first diffraction grating from among the laser light outputted from the light source.

2. The light source device according to claim 1, wherein
a wavelength of the laser light, a pitch of the first diffraction grating, an angle of incidence of the laser light with respect to the first diffraction grating, a divergence angle of the laser light, and an effective refraction index of the optical waveguide path are set to a condition that causes the laser light to be diffracted in one direction of the optical waveguide path and does not cause the laser light to be diffracted in another direction of the optical waveguide path.

3. The light source device according to claim 2, wherein
a center value of the angle of incidence of the laser light falls in a range of not less than 4° and not more than 20°.

4. The light source device according to claim 1, further comprising
an optical waveguide substrate including
a first main surface and a second main surface that is opposed to the first main surface,
the optical waveguide path provided between the first main surface and the second main surface, the optical waveguide path being parallel to the first main surface, and
a mirror layer provided at the second main surface, wherein
the light source unit and the light receiving unit are both mounted at the first main surface.

5. The light source device according to claim 4, wherein
the light source unit includes
an active layer,
first and second DBR (distributed Bragg reflector) layers between which the active layer is interposed,
a first pad section provided to be relatively spaced apart from the light receiving unit, and
a second pad section provided at a position that is relatively close to the light receiving unit,
the optical waveguide substrate includes
a third pad section provided at a position that is opposed to the first pad section, and
a fourth pad section provided at a position that is opposed to the second pad section, and
the light source unit further includes
a first joining section having an electrically conductive property provided between the first pad section and the third pad section and coupling the first pad section and the third pad section to each other, and
a second joining section having an electrically conductive property provided between the second pad section and the fourth pad section and coupling the second pad section and the fourth pad section to each other.

6. The light source device according to claim 5, wherein
a bottom surface of the light source unit is inclined, with respect to the first main surface, in a direction in which the optical waveguide path extends.

7. The light source device according to claim 6, wherein
a size of the first joining section is smaller than a size of the second joining section.

8. The light source device according to claim 6, wherein
sizes of the first pad section and the third pad section are larger than sizes of the second pad section and the fourth pad section.

9. The light source device according to claim 1, wherein
the light source unit and the light receiving unit are integrally formed.

10. The light source device according to claim 1, further comprising
an optical waveguide substrate including
a first main surface and a second main surface that is opposed to the first main surface, and
the optical waveguide path provided between the first main surface and the second main surface, the optical waveguide path being parallel to the first main surface, wherein
the light source unit is mounted at the first main surface, and
the light receiving unit is mounted at the second main surface.

11. The light source device according to claim 1, further comprising
an optical waveguide substrate including
a first main surface and a second main surface that is opposed to the first main surface,
the optical waveguide path provided between the first main surface and the second main surface, the optical waveguide path being parallel to the first main surface, and
the light receiving unit, wherein
the light source unit is mounted at the first main surface.

12. The light source device according to claim 1, wherein
the optical waveguide path further includes a second diffraction grating, and
the light receiving unit is disposed at a position configured to receive light leaking from the optical waveguide path through the second diffraction grating from among the laser light outputted from the light source.

13. The light source device according to claim 6, wherein
the optical waveguide substrate includes a recessed portion at a portion at which the third pad section is formed, and
the third pad section is disposed at a bottom surface of the recessed portion.

14. The light source device according to claim 6, wherein
the light source unit includes a protruding portion at a portion at which the second pad section is formed, and
the second pad section is disposed at a top face of the protruding portion.

15. The light source device according to claim 6, wherein
the optical waveguide substrate includes a protruding portion at a portion at which the fourth pad section is formed, and
the fourth pad section is disposed at a top face of the protruding portion.

16. The light source device according to claim 6, wherein
the light source unit includes a recessed portion at a portion at which the first pad section is formed, and
the first pad section is disposed at a bottom surface of the recessed portion.

17. The light source device according to claim 5, wherein
the first joining section and the second joining section include a solder ball.

18. An electronic apparatus comprising:
a light source device,
the light source device including
an optical waveguide path including a first diffraction grating,
a light source unit that outputs laser light having an optical center axis inclined, with respect to the first diffraction grating, in a direction in which the optical waveguide path extends, and
a light receiving unit that receives light leaking from the optical waveguide path through the first diffraction grating from among the laser light outputted from the light source.
